(19) United States
(12) Patent Application Publication
(10) Pub. No.: US 2024/0110282 A1
(43) Pub. Date: Apr. 4, 2024

(54) LOADLOCK ASSEMBLY INCLUDING CHILLER UNIT

(71) Applicant: ASM IP Holding, B.V., Almere (NL)

(72) Inventor: Hideki Yoshida, Tokyo (JP)

(21) Appl. No.: 18/475,002

(22) Filed: Sep. 26, 2023

Related U.S. Application Data
(60) Provisional application No. 63/377,632, filed on Sep. 29, 2022.

(51) Int. Cl. C23C 16/46; C23C 14/50

(52) U.S. Cl. CPC C23C 16/466; C23C 14/50

(57) ABSTRACT

A loadlock assembly is disclosed. Exemplary loadlock assembly includes a loadlock chamber provided with a plurality of sidewalls, a top portion, a bottom portion, and a plurality of openings through which a substrate is configured to be passed into the loadlock chamber; wherein the loadlock chamber is provided with a plurality of cooling gas intake ports; a substrate support disposed in the loadlock chamber and configured to support the substrate at or near an edge of the substrate; and a chiller unit provided with a plurality of cooling gas nozzles coupled to the cooling gas intake ports and configured to provide a cooling gas that passes through the plurality of cooling gas nozzles to the loadlock chamber.

### CROSS-REFERENCE TO RELATED APPLICATION(S)

This application claims the benefit of U.S. Provisional Application 63/377,632 filed on Sep. 29, 2022, the entire contents of which are incorporated herein by reference.

### FIELD OF INVENTION

The present disclosure relates generally to a loadlock assembly, more particularly, to a loadlock assembly including a chiller unit.

### BACKGROUND OF THE DISCLOSURE

Films may be fabricated on substrates using sequential steps including physical vapor deposition (PVD), chemical vapor deposition (CVD), atomic layer deposition (ALD), etching, epitaxial growth, and annealing to produce a desired device. These steps may be carried out using a variety of processing systems having multiple chambers.

One such system is known as a “cluster tool”. A cluster tool generally includes a central substrate handling chamber or transfer chamber and a number of peripheral chambers including a loadlock chamber and a plurality of process chambers for carrying out processing steps such as deposition, etching, epitaxial growth process, and annealing. The cluster tool also generally includes a robot for transferring substrates between the chambers.

The loadlock chamber typically has a cooling plate to cool the substrate. Temperature gradients may occur across the substrate, which can lead to undesirable stresses in the substrate.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a loadlock assembly is provided. The loadlock assembly comprises a loadlock chamber provided with a plurality of sidewalls, a top portion, a bottom portion, and a plurality of openings through which a substrate is configured to be passed into the loadlock chamber; wherein the loadlock chamber is provided with a plurality of cooling gas intake ports; a substrate support disposed in the loadlock chamber and configured to support the substrate at or near an edge of the substrate; and a chiller unit provided with a plurality of cooling gas nozzles coupled to the cooling gas intake ports and configured to provide a cooling gas that passes through the plurality of cooling gas nozzles to the loadlock chamber.

In various embodiments, the cooling gas nozzles may comprise a center nozzle and a plurality of outer nozzles arranged concentrically.

In various embodiments, the position of the center nozzle may be configured to coincide with a center of the substrate on the substrate support.

In various embodiments, at least one of the cooling gas nozzles may be provided with a plurality of branched nozzles.

In various embodiments, the loadlock assembly may further comprise a mass flow controller configured to control an amount of the cooling gas passing to a backside of the substrate on the substrate support through the cooling gas nozzles.

In various embodiments, each of the cooling gas nozzles may be provided with a main gas valve configured to be opened and closed.

In various embodiments, each of the cooling gas nozzles may be provided with a flow control valve configured to control an amount of the cooling gas.

In various embodiments, each of the cooling gas nozzles may be provided with a flow sensor.

In various embodiments, the loadlock assembly may further comprise a valve controller configured to control the flow control valves.

In various embodiments, the loadlock assembly may further comprise a temperature sensor being configured to measure a temperature of the substrate on the substrate support.

In various embodiments, the valve controller may be communicatively coupled to the temperature sensor, the valve controller being configured to control the flow control valve based on the temperature.

In various embodiments, the cooling gas may be selected from N2, Ar, He, and combination thereof.

In various embodiments, a substrate processing apparatus may comprise; a substrate handling chamber provided with a substrate handling robot to move a substrate; the loadlock assembly, being attached to a side of the substrate handling chamber; and a process chamber to carry out a processing step on the substrate, being attached to another side of the substrate handling chamber.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a schematic cross-sectional view of a substrate processing apparatus in an embodiment of the present invention.

FIG. 2 is a schematic cross-sectional view of a loadlock assembly in an embodiment of the present invention.

FIG. 3a is a schematic cross-sectional view of a chiller unit in an embodiment of the present invention.

FIG. 3b is a schematic cross-sectional view of cooling gas nozzles in FIG. 3a.

FIG. 4a is a schematic cross-sectional view of cooling gas nozzles in an embodiment of the present invention.

FIG. 4b is a schematic cross-sectional view of cooling gas nozzles in an embodiment of the present invention.

FIG. 5 is a timing sequence of a method in an embodiment of the present invention.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

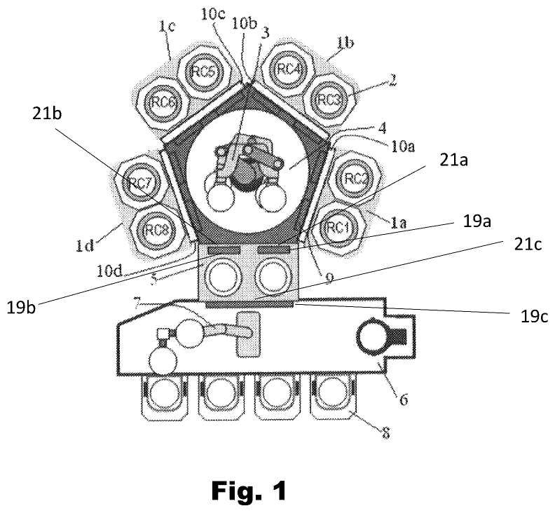

FIG. 1 is a schematic plan view of a substrate processing apparatus in an embodiment of the present invention. The substrate processing apparatus may comprise: (i) four process modules 1a, 1b, 1c, 1d, each having two reaction chambers; (ii) a substrate handling chamber (SHC) 4 including two back end robots 3 (substrate handling robots); and (iii) a load lock chamber (LLC) 5 for loading or unloading two substrates simultaneously, the load lock chamber 5 being attached to the one additional side of the substrate handling chamber 4, wherein each back end robot 3 is accessible to the load lock chamber 5. Each of the back end robots 5 have at least two end-effectors accessible to the two reaction chambers of each unit simultaneously, said substrate handling chamber 4 having a polygonal shape having four sides corresponding to and being attached to the four process modules 1a, 1b, 1c, 1d, respectively, and one additional side for a load lock chamber 4, all the sides being disposed on the same plane. The interior of each process modules 1a, 1b, 1c, 1d and the interior of the load lock chamber 5 may be isolated from the interior of the substrate handling chamber 4 by gate valves 9, 19a, 19b, 19c.

In some embodiments, a controller (not shown) may store software programmed to execute sequences of substrate transfer, for example. The controller may also: check the status of each process chamber; position substrates in each chamber and a cooling state 6 using sensing systems, control a gas box, and an electric box for each module; control a front-end robot 7 in an equipment front end module (EFEM) based on a distribution status of substrates stored in FOUP 8 and the load lock chamber 5; control the back end robots 3; and the control gate valves 9, 19a, 19b, 19c and other valves.

A skilled artisan may appreciate that the apparatus includes one or more controller(s) programmed or otherwise configured to cause the deposition and reactor cleaning processes described elsewhere herein to be conducted. The controller(s) may communicate with the various power sources, heating systems, pumps, robotics, gas flow controllers, or valves, as will be appreciated by the skilled artisan.

In some embodiments, the apparatus may have at least one reaction chamber and process module. In FIG. 1, the apparatus is illustrated to have eight reaction chambers, but it may have 9 or more. In some embodiments, all the modules may have identical capabilities for processing substrates so that the unloading/loading can sequentially and regularly be timed, thereby increasing productivity or throughput. In some embodiments, the modules may have different capabilities (e.g., different treatments) but their handling times may be substantially identical.

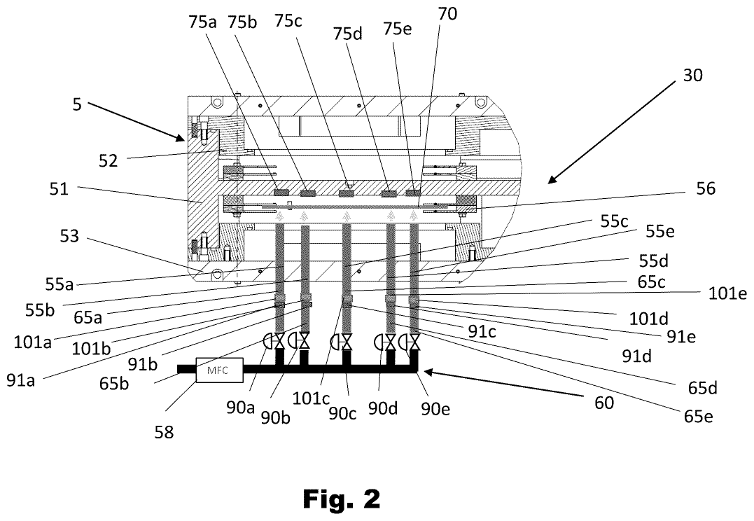

FIG. 2 is a schematic cross-sectional view of a loadlock assembly in an embodiment of the present invention. The loadlock assembly may include a loadlock chamber 5 provided with a plurality of sidewalls 51, a top portion 52, a bottom portion 53, and a plurality of openings 21a to 21c. A substrate 70 may be configured to be passed into the loadlock chamber 5 through the openings 21a to 21c when the gate valves 9a to 9c are opened.

The loadlock chamber 5 may include a plurality of cooling gas intake ports 55a to 55e. A substrate support 56 is disposed in the loadlock chamber 5. The substrate support 56 is configured to support the substrate 70 at or near an edge of the substrate 70.

A chiller unit 60 may include a plurality of cooling gas nozzles 65a to 65e, which are coupled to the cooling gas intake ports 55a to 55e. The chiller unit 60 may be configured to provide a cooling gas that passes through the plurality of cooling gas nozzles 65a to 65e to the loadlock chamber 5. The cooling gas may be selected from N2, Ar, He, and combination thereof.

The cooling gas nozzles 65a to 65e may comprise a center nozzle 65c and a plurality of outer nozzles 65a, 65b, 65d, 65e arranged concentrically. The position of the center nozzle 65c may be configured to coincide with a center of the substrate 70 on the substrate support 56.

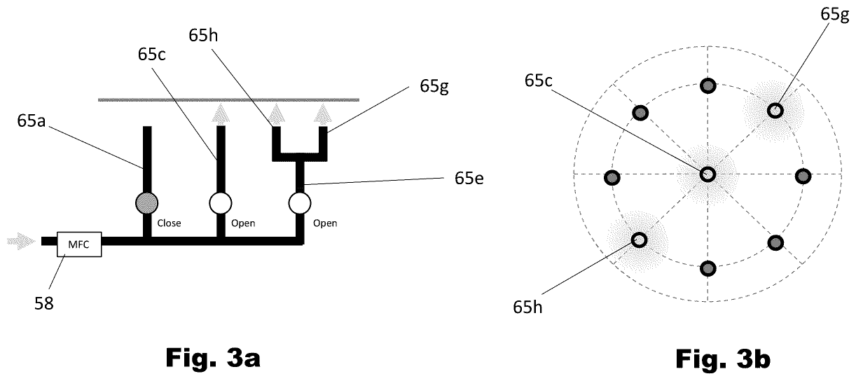

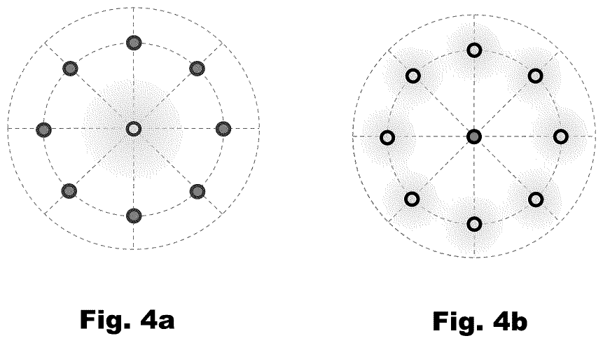

FIG. 3a is a schematic cross-sectional view of a chiller unit in an embodiment of the present invention. FIG. 3b is a schematic cross-sectional view of cooling gas nozzles in FIG. 3a At least one of the cooling gas nozzles 65e may include a plurality of branched nozzles 65g, 65h.

The loadlock assembly may further include a mass flow controller 58. The mass flow controller 58 may be configured to control an amount of the cooling gas passing to a backside of the substrate 70 on the substrate support 56 through the cooling gas nozzles 65a to 65e.

Each of the cooling gas nozzles 65a to 65e may include a main gas valve 90a to 90e. The main gas valves may be configured to be opened and closed. Each of the cooling gas nozzles 65a to 65e may further include a flow control valve 91a to 91e. The flow control valves 91a to 91e may be configured to control an amount of the cooling gas. Each of the cooling gas nozzles 65a to 65e may further include a flow sensor 101a to 101e.

The loadlock assembly may further include a valve controller configured to control the flow control valves 101a to 101e.

The loadlock assembly may further include a plurality of temperature sensors 75a, 75b, 75c, 75d to measure a temperature of the substrate 70 on the substrate support 56. The valve controller may be communicatively coupled to the temperature sensors 75a, 75b, 75c, 75d. The valve controller may be configured to control the flow control valve 91a to 91e based on the temperature.

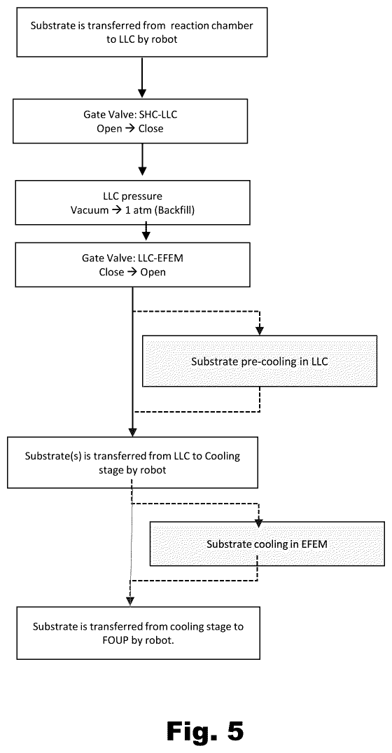

FIG. 5 is a timing sequence of a method in an embodiment of the present invention. In the first step, a substrate is transferred from a reaction chamber to LLC by a back end robot 3. In the second step, gate valves 19a, 19b between SHC and LLC are closed. In the third step, the pressure of LLC changes from vacuum to 1 atm by N2 backfill. In the fourth step, the gate valve 19c between LLC and EFEM is opened. In the fifth step, the substrate pre-cooling step in LLC is performed by using the chiller unit 60. N2 gas provided by the chiller unit 60 is exhausted from EFEM. If it is not necessary to cool the substrate, this step may be canceled. In the sixth step, the substrate is transferred from LLC to the cooling stage 6 or FOUP by the robot 7. In the seventh step, the substrate may be cooled in the cooling stage 6. In the last step, the substrate is transferred from the cooling stage 6 to FOUP by the robot 7.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A loadlock assembly for substrate processing, the loadlock assembly comprising:
a loadlock chamber provided with a plurality of sidewalls, a top portion, a bottom portion, and a plurality of openings through which a substrate is configured to be passed into the loadlock chamber, wherein the loadlock chamber is provided with a plurality of cooling gas intake ports;
a substrate support disposed in the loadlock chamber and configured to support the substrate at or near an edge of the substrate; and
a chiller unit provided with a plurality of cooling gas nozzles coupled to the cooling gas intake ports and configured to provide a cooling gas that passes through the plurality of cooling gas nozzles to the loadlock chamber.

2. The loadlock assembly according to claim 1, wherein the cooling gas nozzles comprise a center nozzle and a plurality of outer nozzles arranged concentrically.

3. The loadlock assembly according to claim 2, wherein the position of the center nozzle is configured to coincide with a center of the substrate on the substrate support.

4. The loadlock assembly according to claim 1, wherein at least one of the cooling gas nozzles is provided with a plurality of branched nozzles.

5. The loadlock assembly according to claim 1, further comprising a mass flow controller configured to control an amount of the cooling gas passing to a backside of the substrate on the substrate support through the cooling gas nozzles.

6. The loadlock assembly according to claim 5, wherein each of the cooling gas is provided with a main gas valve configured to be opened and closed.

7. The loadlock assembly according to claim 5, wherein each of the cooling gas nozzles is provided with a flow control valve configured to control an amount of the cooling gas.

8. The loadlock assembly according to claim 6, wherein each of the cooling gas nozzles is provided with a flow sensor.

9. The loadlock assembly according to claim 7, further comprising a valve controller configured to control the flow control valve.

10. The loadlock assembly according to claim 9, further comprising a temperature sensor being configured to measure a temperature of the substrate on the substrate support.

11. The loadlock assembly according to claim 10, wherein the valve controller communicatively coupled to the temperature sensor, the valve controller being configured to control the flow control valve based on the temperature.

12. The loadlock assembly according to claim 1, wherein the cooling gas is selected from N2, Ar, He, and combination thereof.

13. A substrate processing apparatus, comprising;
a substrate handling chamber provided with a substrate handling robot to move a substrate;
the loadlock assembly according to claim 1, being attached to a side of the substrate handling chamber; and
a process chamber to carry out a processing step on the substrate, being attached to another side of the substrate handling chamber.
